(19) United States
(12) Patent Application Publication
(10) Pub. No.: US 2010/0028812 A1
(43) Pub. Date: Feb. 4, 2010

(54) METHOD OF MANUFACTURING INKJET PRINTHEAD

(75) Inventors: Byung-ha Park, Suwon-si (KR); Young-ung Ha, Suwon-si (KR); Il-woo Kim, Seoul (KR)

Correspondence Address: DLA PIPER LLP US, P. O. BOX 2758, RESTON, VA, 20195, US

(73) Assignee: SAMSUNG ELECTRONICS CO., LTD., Suwon-si (KR)

(21) Appl. No.: 12/332,615

(22) Filed: Dec. 11, 2008

(30) Foreign Application Priority Data
Jul. 31, 2008 (KR) 10-2008-0075348

(51) Int. Cl. G03F 7/20; B44C 1/22; B41J 2/16; B21D 53/76; B24B 1/00

(52) U.S. Cl. 430/320; 216/17; 29/890.1

(57) ABSTRACT

Disclosed is a method of manufacturing an inkjet printhead. The method includes: forming a chamber layer comprising a plurality of ink chambers on a substrate; forming a sacrificial layer comprising water soluble polymer on the chamber layer so as to fill the ink chambers; forming a nozzle layer comprising a plurality of nozzles on the sacrificial layer and the chamber layer; forming an ink feed hole for ink supply in the substrate; and removing the sacrificial layer. The sacrificial layer and the chamber layer may be planarized using a chemical mechanical polishing (CMP) process. The CMP process may utilize a hard polishing, in which an oil based slurry along with polishing pad of hard material to reduce the occurrences of dishing phenomenon.

### CROSS-REFERENCE TO RELATED PATENT APPLICATION

This application claims the benefit of Korean Patent Application No. 10-2008-0075348, filed on Jul. 31, 2008, in the Korean Intellectual Property Office, the disclosure of which is incorporated herein in its entirety by reference.

### BACKGROUND

1. Field of the Related Art

The present disclosure relates to a method of manufacturing a thermal inkjet printhead.

2. Description of the Related Art

Inkjet printheads form an image of a predetermined color by ejecting small ink droplets in a desired position of a printing medium. Such inkjet printheads may be classified into two general types according to the ink droplet ejection mechanisms. One type is a thermal inkjet printhead which ejects ink droplets due to an expansive force of the ink bubbles produced by means of a heat source. The other type is a piezoelectric inkjet printhead, which ejects ink droplets due to pressure applied to ink caused by the deformation of a piezoelectric device.

A general description of the operations of an ink droplet ejection mechanism in a thermal inkjet printhead is as follows. When pulsed current flows through a heater, e.g., formed typically of a resistive heating body, the heat generated by the heater causes the ink adjacent to the heater to substantially instantaneously be heated to about 300° C. As a result, the ink boils, producing ink bubbles. As the ink bubbles expand and apply pressure to the ink filled in the ink chamber, the ink around a nozzle is ejected in the form of droplet(s) through the nozzle.

FIG. 1 is a plan view of a conventional thermal inkjet printhead, and FIG. 2 is a cross-sectional view of the conventional thermal inkjet printhead, taken along line II-II of FIG. 1. Referring to FIGS. 1 and 2, the conventional thermal inkjet printhead comprises a substrate 110, on which a plurality of material layers are formed, a chamber layer 120 that is stacked on the substrate 110 and a nozzle layer 130 that is stacked on the chamber layer 120. A plurality of ink chambers 122 in which ink to be ejected is filled are formed in the chamber layer 120, and a plurality of nozzles 132, through which ink is ejected, are formed in the nozzle layer 130. An ink feed hole 111 for supplying ink to the ink chambers 122 is formed in the substrate 110. In addition, a plurality of restrictor 124, which connect the ink chambers 122 and the ink feed hole 111, may be formed in the chamber layer 120. The substrate 110 may be generally a silicon substrate, and the chamber layer 120 and the nozzle layer 130 may be formed of polymer, which may be epoxy based. A glue layer 121 may be further formed between the substrate 110 and the chamber layer 120 for increasing the adhesion therebetween.

An insulation layer 112 for providing insulation between a plurality of heaters 114 and the substrate 110 may further be formed on the substrate 110. The heaters 114 which heat ink to generate bubbles are formed on the insulating layer 112 to correspond to the ink chambers 122, and a plurality of electrodes 116 may be formed on the heaters 114. A passivation layer 118 may be formed on the heaters 114 and the electrodes 116. An anti-cavitation layer 119, which protects the heaters 114 from a cavitation force that may be generated when bubbles burst, may be formed on the passivation layer 118.

In order to manufacture the inkjet printhead having the above structure, the chamber layer 120, in which the ink chambers 122 are formed, is formed on the substrate 110, on which the heaters 114 and the electrodes 116, etc., are sequentially formed. A sacrificial layer is formed on the chamber layer 120 to fill the ink chambers 122. The sacrificial layer may conventionally be formed of a water insoluble photoresist material, such as, e.g., the ODUR™ product available from Tokyo Ohka Kogyo Co., Ltd. of Japan, which is a positive photoresist. The ODUR material is formed of approximately 10-25% monopolymer MIPK (3-methyl-2-butane) and approximately 75-90% cyclohexanone. A chemical mechanical polishing (CMP) process then is performed to planarize the top surface of the sacrificial layer. During the CMP process, a water based slurry, in which silica or alumina particles are dispersed, and a soft pad, based on, e.g., polyurethane material, may be used. Subsequently, after the nozzle layer 130 including the nozzles 132 is formed atop the planarized chamber layer 120 and sacrificial layer, the ink feed hole 111 for ink supply is formed in the substrate 110. The sacrificial layer occupying the internal volume of the ink chamber 122 is then removed by using an organic solvent, such as, e.g., lactate, thereby completing the inkjet printhead.

Unfortunately, however, the ODUR used as the sacrificial layer material during the above described fabrication suffers from many disadvantages. The ODUR is a relatively expensive photosensitive resin. Due to the relatively low viscosity of the ODUR, the process of filling the ink chambers 122 may need to be performed multiple times, resulting in the increased costs and time in the manufacturing the inkjet printhead. When the CMP process is performed on the sacrificial layer using the aforementioned slurry and pad, a dishing phenomenon whereby after the planarization process the height of the sacrificial layer becomes shorter than the height of the chamber layer 120 may occur. In addition, the solvent contained in the ODUR material, i.e., cyclohexanone, may react with the nozzle layer 130. It also takes a long time to remove the sacrificial layer by using the organic solvent, such as lactate, and the structure body of the printhead may become damaged during the long-process of removing the sacrificial layer.

### SUMMARY OF DISCLOSURE

According to an aspect of the present invention, there is provided a method of manufacturing an inkjet printhead, comprising: forming a chamber layer comprising a plurality of ink chambers on a substrate; forming a sacrificial layer to fill the plurality of ink chambers, the sacrificial layer comprising water soluble polymer; forming a nozzle layer comprising a plurality of nozzles above the sacrificial layer and the chamber layer; forming an ink feed hole in the substrate, the ink feed hole providing an ink supply path, through which ink is supplied to the ink chambers; and removing the sacrificial layer.

The water soluble polymer may comprise at least one of polyvinyl alcohol (PVA), polyvinyl pyrolidone (PVP) and carboxylmethyl cellulose.

The method may further comprise planarizing the sacrificial layer and the chamber layer by a chemical mechanical polishing (CMP) process utilizing an oil based slurry.

The oil based slurry may comprise diamond particles dispersed therein.

The CMP process may be performed using a polishing pad comprised of at least one of metal and ceramics.

The step of removing the sacrificial layer may comprise subjecting the sacrificial layer to a water soluble solution.

The water soluble solution may comprise one of water and a mixture of water and isopropyl alcohol.

The step of removing the sacrificial layer may comprise injecting the water soluble solution through at least one of the plurality of nozzles.

The method may further comprise: forming an insulating layer on the substrate; forming, on the insulating layer, a plurality of heaters and a plurality of electrodes; forming a passivation layer over the heaters and the electrodes; and selectively etching portions of the passivation layer and the insulating layer to form a trench through which the substrate is exposed.

The method may further comprise forming an anti-cavitation layer over the passivation layer.

The method may further comprise forming a glue layer on the passivation layer, the glue layer promoting adhesion between the chamber layer and the passivation layer.

The step of forming the ink feed hole may comprise: etching the back side of the substrate to form the ink feed hole to extend to the trench.

The step of forming the chamber layer may comprise: depositing a photosensitive epoxy resin on the substrate; and patterning the photosensitive epoxy resin using a photolithography process.

The step of forming the nozzle layer may comprise: depositing a photosensitive epoxy resin on the substrate; and patterning the photosensitive epoxy resin using a photolithography process.

According to another aspect of the present invention, a method of manufacturing an inkjet printhead may comprise: forming a chamber layer comprising a plurality of ink chambers on a substrate; forming a sacrificial layer to fill the plurality of ink chambers; planarizing the sacrificial layer and the chamber layer by a chemical mechanical polishing (CMP) process that uses an oil based slurry; and forming a nozzle layer comprising a plurality of nozzles above the planarized sacrificial layer and the chamber layer.

The oil based slurry may comprise diamond particles dispersed therein.

The CMP process may be performed using a polishing pad comprised of at least one of metal and ceramics.

The sacrificial layer may comprise water soluble polymer.

The water soluble polymer may comprise at least one of polyvinyl alcohol (PVA), polyvinyl pyrolidone (PVP) and carboxyl methyl cellulose.

The method may further comprise: forming an ink feed hole in the substrate, the ink feed hole providing an ink supply path, through which ink is supplied to the ink chambers; and removing the sacrificial layer by injecting the Water soluble solution through at least one of one or more of the plurality of nozzles and the ink feed hole.

### BRIEF DESCRIPTION OF THE DRAWINGS

Various features and advantages of the embodiments of the present invention will become apparent and more readily appreciated from the following description of the embodiments, taken in conjunction with the accompanying drawings, of which:

FIG. 1 is a plan view of an example of a conventional thermally driven inkjet printhead;

FIG. 2 is a cross-sectional view of the conventional thermal inkjet printhead, taken along line II-II of FIG. 1; and

FIGS. 3 through 9 illustrate a method of manufacturing an inkjet printhead according to embodiments of the present invention.

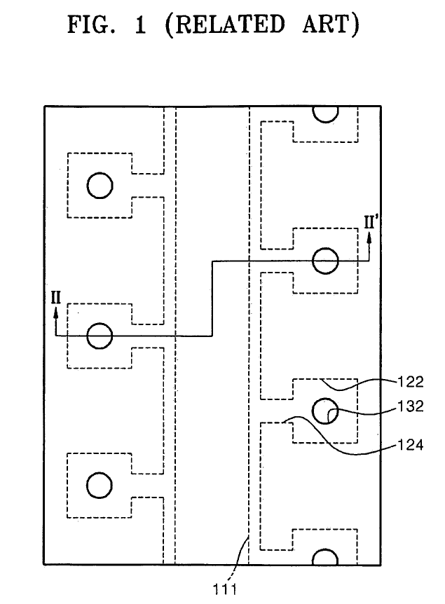

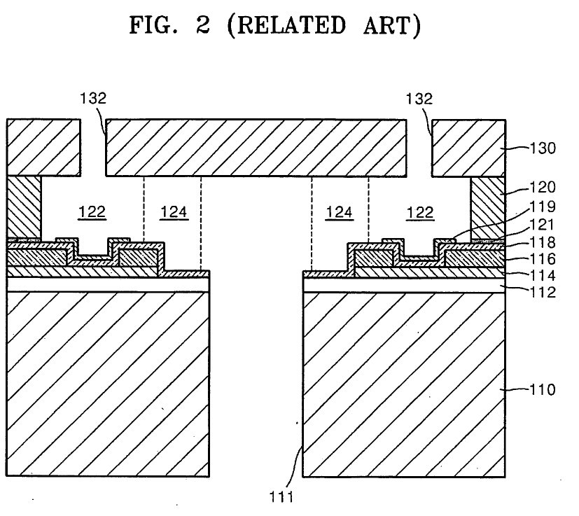

### DETAILED DESCRIPTION OF SEVERAL EMBODIMENTS

Reference will now be made in detail to embodiments of the present invention, examples of which are illustrated in the accompanying drawings, wherein like reference numerals refer to like elements. While the embodiments are described with detailed construction and elements to assist in a comprehensive understanding of the various applications and advantages of the embodiments, it should be apparent however that the embodiments can be carried out without those specifically detailed particulars. For example, it will also be understood that when a layer is referred to as being “on” another layer or substrate, it can be directly on the other layer or substrate, or intervening layers may be present. A different material from the examples disclosed herein may be used to form each of the elements of the inkjet printhead, and the sequence of each of steps of manufacturing the inkjet printhead may be changed as occasion demands. Well-known functions or constructions will not be described in detail so as to avoid obscuring the description with unnecessary detail. It should be also noted that in the drawings, the dimensions of the features are not intended to be to true scale, and may be exaggerated for the sake of enabling a greater understanding.

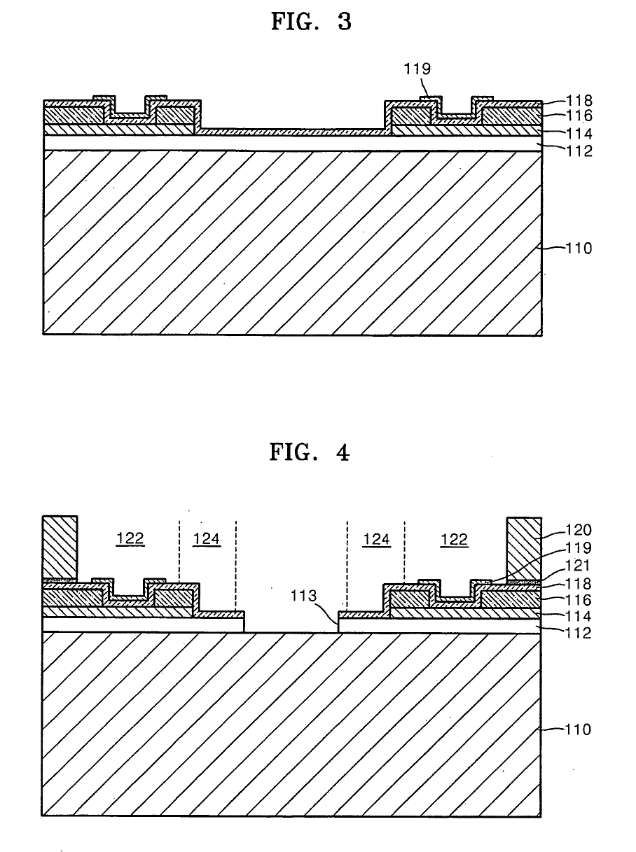

FIGS. 3 through 9 illustrate a method of manufacturing an inkjet printhead according to embodiments of the present invention.

Referring to FIG. 3, as the initial steps, a substrate 110 is prepared, and an insulating layer 112 is formed on the substrate 110. The substrate 110 may be, e.g., a silicon substrate. The insulating layer 112 provides the insulation between the substrate 110 and a plurality of heaters 114, which will be described later, and may be formed of, e.g., silicon oxide. Subsequently, the heaters 114 are formed on the insulating layer 112. The heaters 114 may be formed by depositing a resistive material, such as, for example, without limitation, tantalum-aluminum alloy, a tantalum nitride, a titanium nitride or a tungsten silicide, or the like, on the insulating layer 112, and then by patterning the resistance heating bodies 114. A plurality of electrodes 116 are formed on the heaters 114 so as to apply current to the heaters 114. The electrodes 116 may be formed by depositing metal having excellent electrical conductivity, such as, e.g., aluminum (Al), an aluminum alloy, gold, silver, or the like, on top surfaces of the heaters 114 and then by patterning the metal.

A passivation layer 118 may be formed to cover the insulating layer 112, the heaters 114 and the electrodes 116. The passivation layer 118 may prevent the heaters 114 and the electrodes 116 from oxidizing or corroding due to contact with ink, and may be formed of a silicon nitride or a silicon oxide, for example. An anti-cavitation layer 119 may further be formed on the passivation layer 118 at positions above the heaters 114. The anti-cavitation layer 119 protects the heaters 114 from a cavitation force generated when bubbles are destroyed, and may be formed of tantalum (Ta), for example.

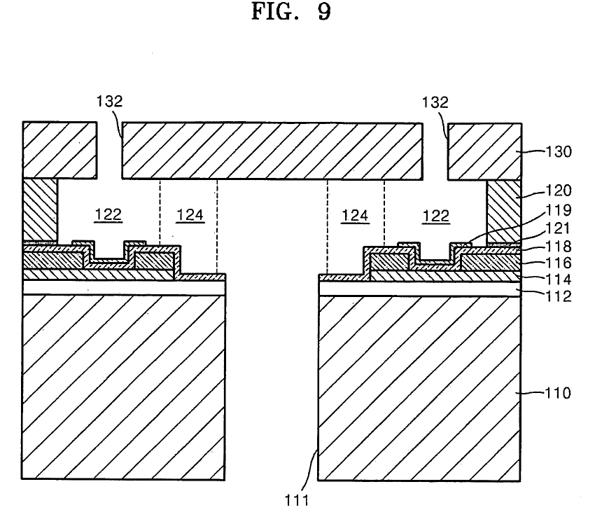

Referring to FIG. 4, a glue layer 121 may be further formed on the passivation layer 118. The glue layer 121 is used to increase the gluing force between the passivation layer 118 and the chamber layer 120, which will be described further later. Subsequently, the passivation layer 118 and the insulating layer 112 are etched, sequentially according to an embodiment, thereby forming a trench 113 exposing the top surface of the substrate 110. The trench 113 may be formed above the ink feed hole (111 of FIG. 9), which will be described later, to form the ink supply path. According to an embodiment, the trench 113 may be formed to extend into the substrate 110 by etching the upper portion of the substrate 110 to certain depth.

Next, the chamber layer 120, in which a plurality of ink chambers 122 are formed, is formed on the passivation layer 118. The chamber layer 120 may be formed by applying a predetermined material, for example, a photosensitive epoxy resin, to a predetermined thickness on the passivation layer 116 and then by patterning the photosensitive epoxy resin by using a photolithography process so that the ink chambers 122, in which ink to be ejected is filled, is formed in the chamber layer 120 to correspond to the heaters 114. The ink chambers 122 may be positioned above the heaters 114. A plurality of restrictors 124 may further be formed in the chamber layer 120. The restrictors 124 are paths that connect the ink chambers 122 and an ink feed hole (111 of FIG. 9), which will be described later.

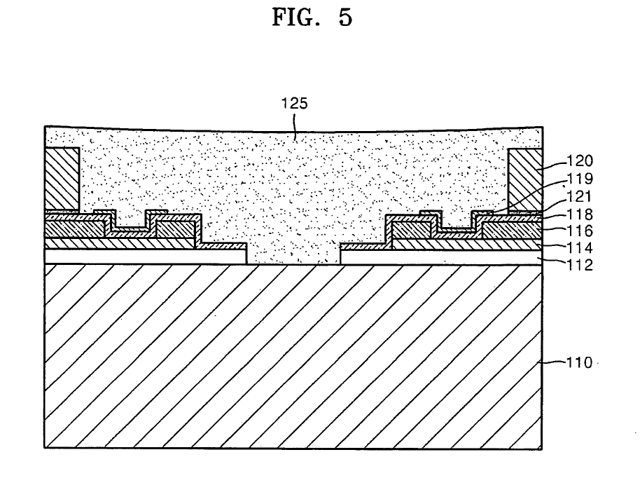

Referring to FIG. 5, a sacrificial layer 125 is formed on the chamber layer 120 so as to cover the trench 113, the ink chambers 122, and the restrictor 124. According to an embodiment, the sacrificial layer 125 may comprise a water soluble polymer, which may be, for example, one material selected from the group consisting of polyvinyl alcohol (PVA), polyvinyl pyrolidone (PVP), carboxyl methyl cellulose, and mixture thereof. However, the present inventive method is not limited to the use of the above example water soluble material.

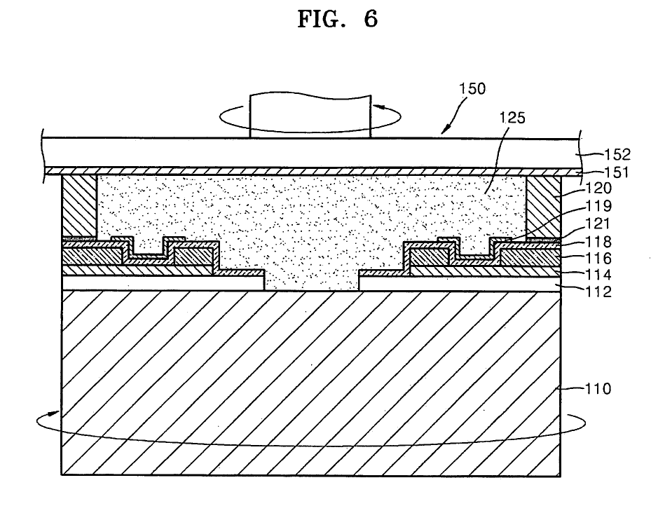

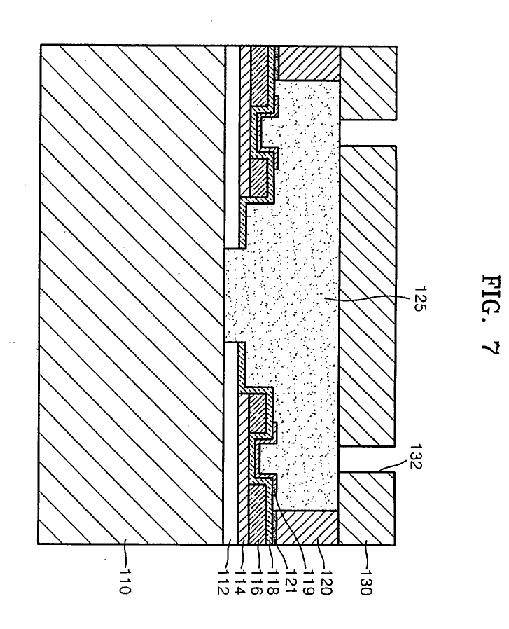

Referring to FIG. 6, the top surface of each of the sacrificial layer 125 and the chamber layer 120 may be planarized by using a chemical mechanical polishing (CMP) process. Reference numeral 150 denotes a polishing device used for the CMP process. The polishing device may comprise a polishing pad 151 which is rotated while applying a predetermined pressure to the top surface of each of the chamber layer 120 and the sacrificial layer 125, which are formed on the substrate 110, and a platen 152 which rotates the polishing pad 151. According to the current embodiment, an oil based slurry may be used as a slurry in the CMP process in light of the water soluble nature of the sacrificial layer 125. Particles formed of a hard material, such as diamond particles, may be dispersed in the slurry. In addition, according to an embodiment, the polishing pad 151 used for the CMP process may comprise a hard material, such as metal, ceramics or a mixture thereof. The metal may be iron, copper, tin, lead, etc, for example.

According to an embodiment, by performing the CMP process using the oil based slurry and the polishing pad 151 formed of a hard material, the chamber layer 120 may be made to a desired height. In addition, a dishing phenomenon, in which the height of the sacrificial layer 125 becomes smaller than the height of the chamber layer 120 at the completion of the planarization process, may be substantially reduced. Specifically, because a conventional polishing pad used in a conventional CMP process is formed of a soft material, such as polyurethane, etc., the conventional CMP process is generally referred to as soft polishing. When the oil based slurry is used in a soft polishing process, the polishing pad melts and disintegrates. Thus, the oil based slurry as used in the current embodiment may not be suitable for the soft polishing process. Meanwhile, the CMP process used in the current embodiment is referred to as hard polishing because the polishing pad 151 used in the CMP process is formed of a hard material, such as, metal, or the like. According to an embodiment, the polishing pad 151 may be formed as an integrated body with the platen 152. In the hard polishing process, the replacement cycle for the consumable components, such as, e.g., the polishing pad 151, can be extended. The hard polishing process may also result in an improved planarization of the sacrificial layer 125 and the chamber layer 120 over the soft polishing process. Thus, a nozzle layer 130 may be formed with a better uniformity in thickness on the top surface of each of the sacrificial layer 125 and the chamber layer 120 during the subsequent process.

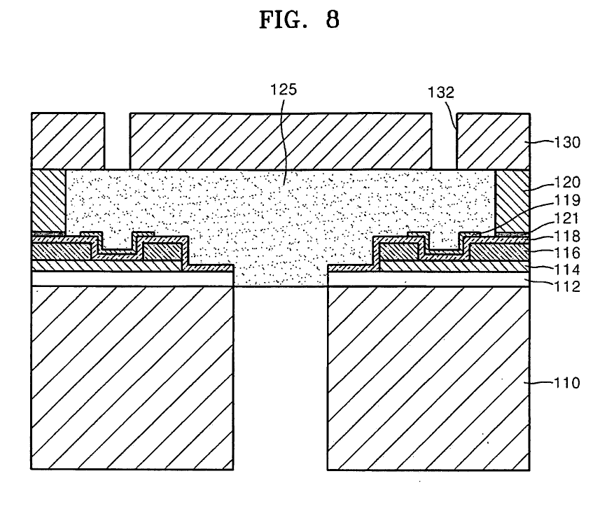

Referring to FIG. 7, the nozzle layer 130 in which a plurality of nozzles 132 are formed, is formed on the top surfaces of the chamber layer 120 and the sacrificial layer 125, which were planarized by using the CMP process as above described. The nozzle layer 130 may be formed by applying certain material, for example, a photosensitive epoxy resin, on the top surfaces of the chamber layer 120 and the sacrificial layer 125 and then by patterning the photosensitive epoxy resin by using a photolithography process so as to result in the nozzles 132, through which the sacrificial layer 125 is exposed, being formed in the nozzle layer 130. The nozzles 132 may be positioned above the ink chambers 122.

Referring to FIG. 8, the rear side of the substrate 110 is etched, thereby forming an ink feed hole (111 of FIG. 9) for supplying the ink. The ink feed hole 111 may be formed by dry etching the rear side of the substrate 110 until the bottom surface of the sacrificial layer 125 at the trench 113 is exposed. Referring to FIG. 9, the sacrificial layer 125 which is filled in the trench 113, the ink chambers 122, and the restrictor 124, is removed so that an inkjet printhead is manufactured. The sacrificial layer 125 may be removed by injecting an etchant, which is used to selectively etch the sacrificial layer 125, through the nozzles 132 and/or the ink feed hole 111. According to an embodiment, the sacrificial layer 125 is formed of water soluble polymer. Thus, a water soluble solution is used as the etchant for removing the sacrificial layer 125. The water soluble solution may be, e.g., water or a mixture of water and isopropyl alcohol. However, the present inventive method is not limited to the use of the above examples, and other water soluble solution may be used. When the water soluble solution is used as the etchant, the sacrificial layer 125 may be removed within a comparatively short time. By removing the sacrificial layer 125, the ink chambers 122 and the restrictors 124, which connects the ink chambers 122 and the ink feed hole 111, are formed in the chamber layer 120.

As described above, in the method of manufacturing the inkjet printhead according to the embodiments of the present invention, the sacrificial layer 125 is formed using water soluble polymer, and a water soluble solution is used as the etchant for removing the sacrificial layer 125 such that the time required for removing the sacrificial layer 125 can be reduced and the time required for the process of manufacturing the inkjet printhead can be reduced. In addition, due to the reduction of the time required for the process of manufacturing the inkjet printhead, damages to the structure(s) of the inkjet printhead from a prolonged exposure to etchant can be prevented. Since water soluble polymer is material having higher viscosity than conventionally used resin material, e.g., ODUR, the number of fill-up processes of filling the ink chambers 122 can be reduced and the time required for the process of manufacturing the inkjet printhead can also be reduced. Furthermore, a CMP process is performed using an oil based slurry and the polishing pad 151 formed of a hard material such that the chamber layer 120 can be formed to a desired height and dishing phenomenon, in which the height of the sacrificial layer 125 become smaller than the height of the chamber layer 120 after the planarization process, can be prevented from occurring. As a result, deformation of the nozzle layer formed on the chamber layer can be prevented to improve the uniformity of ejection characteristic of the inkjet printhead.

While the present general inventive concept has been particularly shown and described with reference to embodiments thereof, it will be understood by those of ordinary skill in the art that various changes in form and details may be made therein without departing from the spirit and scope of the present general inventive concept as defined by the following claims.

What is claimed is:

1. A method of manufacturing an inkjet printhead, comprising:
forming a chamber layer comprising a plurality of ink chambers on a substrate;
forming a sacrificial layer to fill the plurality of ink chambers, the sacrificial layer comprising water soluble polymer;
forming a nozzle layer comprising a plurality of nozzles above the sacrificial layer and the chamber layer;
forming an ink feed hole in the substrate, the ink feed hole providing an ink supply path, through which ink is supplied to the ink chambers; and
removing the sacrificial layer.

2. The method of claim 1, wherein the water soluble polymer comprises at least one of polyvinyl alcohol (PVA), polyvinyl pyrolidone (PVP) and carboxyl methyl cellulose.

3. The method of claim 1, further comprising:
planarizing the sacrificial layer and the chamber layer by a chemical mechanical polishing (CMP) process utilizing an oil based slurry.

4. The method of claim 3, wherein the oil based slurry comprises diamond particles dispersed therein.

5. The method of claim 3, wherein the CMP process is performed using a polishing pad comprised of at least one of metal and ceramics.

6. The method of claim 1, wherein the step of removing the sacrificial layer comprises subjecting the sacrificial layer to a water soluble solution.

7. The method of claim 6, wherein the water soluble solution comprises one of water and a mixture of water and isopropyl alcohol.

8. The method of claim 6, wherein the step of removing the sacrificial layer comprises injecting the water soluble solution through at least one of the plurality of nozzles.

9. The method of claim 1, further comprising:
forming an insulating layer on the substrate;
forming, on the insulating layer, a plurality of heaters and a plurality of electrodes;
forming a passivation layer over the heaters and the electrodes; and
selectively etching portions of the passivation layer and the insulating layer to form a trench through which the substrate is exposed.

10. The method of claim 9, further comprising:
forming an anti-cavitation layer over the passivation layer.

11. The method of claim 10, further comprising:
forming a glue layer on the passivation layer, the glue layer promoting adhesion between the chamber layer and the passivation layer.

12. The method of claim 9, wherein the step of forming the ink feed hole comprises:
etching the back side of the substrate to form the ink feed hole to extend to the trench.

13. The method of claim 1, wherein the step of forming the chamber layer comprises:
depositing a photosensitive epoxy resin on the substrate; and
patterning the photosensitive epoxy resin using a photolithography process.

14. The method of claim 1, wherein the step of forming the nozzle layer comprises:
depositing a photosensitive epoxy resin on the substrate; and
patterning the photosensitive epoxy resin using a photolithography process.

15. A method of manufacturing an inkjet printhead, comprising:
forming a chamber layer comprising a plurality of ink chambers on a substrate;
forming a sacrificial layer to fill the plurality of ink chambers;
planarizing the sacrificial layer and the chamber layer by a chemical mechanical polishing (CMP) process that uses an oil based slurry; and
forming a nozzle layer comprising a plurality of nozzles above the planarized sacrificial layer and the chamber layer.

16. The method of claim 15, wherein the oil based slurry comprises diamond particles dispersed therein.

17. The method of claim 15, wherein the CMP process is performed using a polishing pad comprised of at least one of metal and ceramics.

18. The method of claim 15, wherein the sacrificial layer comprises water soluble polymer.

19. The method of claim 18, wherein the water soluble polymer comprises at least one of polyvinyl alcohol (PVA), polyvinyl pyrolidone (PVP) and carboxyl methyl cellulose.

20. The method of claim 18, further comprising:
forming an ink feed hole in the substrate, the ink feed hole providing an ink supply path, through which ink is supplied to the ink chambers; and
removing the sacrificial layer by injecting the water soluble solution through at least one of one or more of the plurality of nozzles and the ink feed hole.
